(19) United States
(12) Patent Application Publication
(10) Pub. No.: US 2003/0213561 A1
(43) Pub. Date: Nov. 20, 2003

(54) Atmospheric pressure plasma processing reactor

(76) Inventors: Gary S. Selwyn, Los Alamos, NM (US); Ivars Henins, Los Alamos, NM (US); Hans Snyder, Los Alamos, NM (US); Hans W. Herrmann, Los Alamos, NM (US)

Correspondence Address: UNIVERSITY OF CALIFORNIA, LOS ALAMOS NATIONAL LABORATORY, P.O. BOX 1663, MS A187, LOS ALAMOS, NM, 87545, US

(21) Appl. No.: 10/208,124

(22) Filed: Jul. 29, 2002

Related U.S. Application Data
(63) Continuation-in-part of application No. 09/804,593, filed on Mar. 12, 2001, now abandoned.

(51) Int. Cl. H01L 21/306; C23C 16/00

(52) U.S. Cl. 156/345.43; 156/345.47; 156/345.33; 156/345.34; 118/723 E; 118/719; 156/345.32

(57) ABSTRACT

An atmospheric pressure plasma etching reactor, in one embodiment, has a table holding a wafer to be processed and which moves the wafer to be processed under at least one electrode that is mounted in close proximity to the table and defines an entry of a gas mixture, and in another embodiment, has interleaved radio frequency powered electrodes and grounded electrodes. Electrodes may have grooves having preselected widths to enhance the plasma for treatment of the wafers. With a radio-frequency voltage connected between the electrodes, and a gas mixture between the electrode and the wafer, a plasma is created between the electrode and the wafer to be processed, resulting in surface treatment, film removal or ashing of the wafer.

This is a continuation-in-part application out of U.S. patent application Ser. No. 09/804,593, filed Mar. 12, 2001, now abandoned.

This invention was made with Government support under Contract No. W-7405-ENG-36 awarded by the U.S. Department of Energy. The Government has certain rights in the invention.

### FIELD OF THE INVENTION

The present invention generally relates to plasma generation for use in material treatment, deposition or etching processes, and, more specifically to a processing reactor for generating a plasma at atmospheric pressure to be used for treatment of a silicon wafer or material substrate.

### BACKGROUND OF THE INVENTION

Integrated circuits have become pervasive components of myriad products the world uses everyday. They are found in household products, cell phones, computers, radios and virtually thousands of additional application. Because of the demand for these products, it is imperative that the manufacture of integrated circuits produces efficacious and reliable devices in the most efficient and cost effective manner possible.

One of the critical steps in the manufacture of integrated circuits is the step of plasma ashing, or removal, of photoresist. Photoresist is an organic, photosensitive compound that is applied as a thin film over a wafer in order to photographically transfer a circuit pattern to the surface of the wafer. The photoresist is first “developed” with the circuit pattern and then the developed photoresist is used as a mask to selectively define regions of the wafer that will be etched using a chemically-reactive plasma. After the silicon etching process is complete, and the etched pattern has been transferred to the wafer, the residual photoresist mask must be removed, or “ashed” off the surface of the wafer, in preparation for the next process step. It is important that removal of all the photoresist material from the wafer be done in this ashing step, to avoid contamination in subsequent process steps. As used herein, the term “wafer” shall mean any material substrate, including but not limited to silicon wafers, glass panels, dielectrics, metal films or semiconductor materials.

Present systems for achieving this photoresist removal include wet processes, done using solvents, and dry processes accomplished by oxidation of the photoresist layer using ozone or oxygen-containing plasmas. The latter method is often called photoresist “ashing.” Wet photoresist removal steps generate chemical waste, which must be disposed of properly. Dry processes, such as plasma ashing, involve the use of a vacuum chamber in which the plasma is generated, which increases the cost of the equipment. A drawback in the use of ozone for photoresist removal is the danger and toxicity of this relatively unstable, noxious gas.

Plasma ashing is the generally preferred means of photoresist removal. However, because the wafers are individually processed in vacuum, each step requires a separate vacuum chamber so that a single process chemistry is used within a single chamber in order to avoid chemical contamination between sequential process steps. This means that, should multiple process steps be necessary, multiple vacuum chambers are required. Naturally, with multiple vacuum chambers, a wafer must be moved from one chamber to the next, slowing wafer throughput. In addition, each vacuum chamber must have separate gate values, vacuum pumps and gauges. This increases the cost and complexity of the process. Multiple process steps are often desirable to use in photoresist ashing as described herein. While the use of multiple processing steps is possible using the prior art, the need for separate vacuum process chambers to accommodate the different chemistries adds to the cost and complexity of the present method, and reduces wafer throughput.

In some process steps required for device fabrication, ion implantation is used to change the conductivity of the silicon matrix. When using this process, it is necessary that selected regions of the silicon substrate be exposed to certain ions having a desired kinetic energy in order to be implanted into the silicon substrate to a desired depth, so that the localized electrical properties of the semiconductor wafer is changed in a desired manner.

Photoresist masking also is used with the ion implantation process. In those regions of the semiconductor wafer where photoresist exists, the photoresist acts as a barrier, preventing ion implantation in those regions, but allowing the ions to penetrate in those regions where the photoresist is not present. The high energy and chemical properties of the ions cause the photoresist to harden and polymerize, forming a thick “skin” that that makes removal more difficult. As a further complication, inorganic species from the ion implantation process become embedded in this thickened “skin”.

Because the ions are typically As⁺, B⁺, or P⁺, the hardened photoresist is no longer a purely organic compound capable of reaction with oxygen plasmas to form volatile etch products, such as CO, CO₂ and H₂O. To remove the hardened photoresist, halogen plasma reactants, such as atomic fluorine, in addition to atomic oxygen, are often required. Accordingly, fluorine-based feedgases, such as CF₄, are used in the plasma to generate the necessary atomic fluorine, which is highly reactive to both photoresist and to the dopant species, thereby helping to etch away the implanted surface of the hardened photoresist. Of course, if a fluorine-based processed is operated for too long a period and the photoresist is completely removed, there is danger of the fluorine atoms reacting with the silicon substrate, and causing undesirable and uncontrolled etching of the silicon substrate. For this reason, diligent ashing of hardened photoresist calls for a short exposure to a fluorine-containing plasma, used to remove the upper layers of the hardened photoresist, followed by a second plasma exposure to a pure oxygen plasma, in order to avoid etching of the silicon substrate.

Alternatively, physical sputtering may be used to help remove the hardened photoresist film. Physical sputtering utilizes the kinetic energy of ions, typically Ar⁺, impacting a film to help remove surface material. Sputtering is a physical momentum transfer process that does not rely upon the formation of volatile, chemical etch products. In this way, the inorganic, ion-implanted components and the cross-linked, polymerized organic components of the photoresist film can be removed. While this process is effective, it is slow and can also present the risk of damage to the delicate device structures beneath the photoresist.

To avoid the damage effects caused by high energy sputtering, a combination of both reactive, plasma chemistry and ion-enhanced etching can be employed in plasma processing of semiconductors. In this approach, the substrate is exposed to reactive etchants generated by the plasma, such as F, and to a flux of ions. In contrast to sputtering, the ion flux has kinetic energy lower than that employed in sputtering applications and serves the role of enhancing the chemical etching process. This process is called reactive ion etching (RIE). RIE provides faster etching than purely chemical etching, such as would be obtain in “downstream” plasma processing, but can still present a possibility of substrate damage, especially if the substrate remains exposed to the enhanced ion flux when the photoresist layer is fully removed.

As discussed above, plasma ashing of hardened photoresist requires at least two process steps: one with an aggressive plasma step, employing either high energy ions to cause sputtering or reactive ion etching with a fluorine-based process chemistry; and the other involving a gentle, oxygen-based chemistry for removal of the soft photoresist remaining after the hardened skin has been removed and to avoid damage to the underlying device. This two step process requires a determination between operation of each of the steps in two different vacuum chambers, or in a single vacuum chamber that operates sequentially with each process.

Generally, the use of two different vacuum chambers has been preferred because it reduces the likelihood of chemical cross contamination due to the residual presence of gas from the previous process step. This is the most expensive and complicated approach since it requires two vacuum process chambers, dual pumps and gauges, and a means of moving wafers between the two process chambers, while keeping them in vacuum. Also, corrosion of the vacuum chamber is increased by the repeated use of different process chemistries in a single chamber. Wall corrosion causes flaking of particle contaminants from wall, which contaminates the wafer.

As discussed above, the best method for processing hardened photoresist requires that the wafer be transported first to a plasma chamber that operates with a fluorine-based chemistry, preferably with increased ion flux onto the afer, and then to another chamber that operates with an oxygen-based chemistry and with a “weaker” or more gentle plasma having less ion flux onto the wafer. Consequently, the removal of ion-hardened photoresist in a conventional vacuum-based plasma ashing tool is a slow and expensive undertaking. In addition to the necessary two process chambers, there also must be an automated load-lock chamber that functions as an interface between atmospheric pressure and the vacuum environment of the ashing tool.

The present invention simplifies this process, and provides ashing capability far superior to the prior art, especially for hardened photoresist. Unlike the prior art, the present invention provides a novel means for providing a continuous variation in plasma density and ion flux needed to remove the hardened “skin” of ion-implanted photoresist, while also providing a gentle plasma that will not damage the underlying device elements, once the photoresist is removed. The invention does this at less cost than the conventional technology because of the much higher efficiency attained. It accomplishes these improvements through an atmospheric pressure system that permits it to complete several process steps without the need for vacuum transfers and without cross contamination between the process units that operate with different gas chemistries. It provides a means by which the wafer may be sequentially processed through different plasma stages in which the ion flux is intentionally increased at the onset and then decreases sequentially as the hardened photoresist film is removed.

It uses topographically-designed, interchangeable electrodes that may be used separately or in combination to provide either an “aggressive” (i.e., ion-enhanced) or “gentle” (i.e., lower ion density) plasma selected to the needs of the user. The aggressive plasma process would be used to remove a hardened top surface of the photoresist; the gentle plasma would be used to remove convention photoresist (i.e., not ion-implanted) or ion-planted photoresist after the hardened skin had been removed. As used herein, an atmospheric pressure plasma is defined as a plasma operating at pressure in excess of 200 Torr and less than 10,000 Torr.

For purposes of discussion herein, a vacuum chamber is defined as a vacuum-tight, sealed unit capable of being pumped down to a low base pressure and refilled with the process gas for the purpose of generating a plasma. It also would be fitted with necessary vacuum pumps and vacuum gauges, and would be entirely constructed of vacuum-compatible materials.

An enclosure used with the present invention is defined as leak-tight box that can contain a mix of process gas without contamination from outside air and which provides the necessary means for prevention of operator exposure to hazardous gases generated by the plasma. An enclosure herein does not need the structural stability required for vacuum operation and does not use vacuum pumps, vacuum gauges or load-locks capable of transferring substrates from room air to a vacuum chamber.

The present invention is loosely related to a recently filed U.S. patent application Ser. 09/776,086, filed Feb. 2, 2001, for Processing Materials Inside an Atmospheric-Pressure Radio Frequency Nonthermal Plasma Discharge.

It is therefore an object of the present invention to provide substrate processing that is capable of processing multiple substrates in sequence at atmospheric pressure.

It is another object of the present invention to provide substrate processing that is capable of parallel processing of multiple substrates for simultaneous ashing or surface treatment.

It is yet another object of the present invention to provide a substrate processing system capable of providing multiple processing steps to a given substrate within a single process enclosure.

It is still another object of the present invention to provide substrate processing that is capable of using different plasma chemistries within the same enclosure, thereby eliminating the need for load locks, multiple chambers and wafer handling delays.

And it yet another object of the present invention to provide, within a single enclosure, a means of exposing a substrate to plasma density that varies in ion density from aggressive to gentle in order to provide a range of process conditions.

Additional objects, advantages and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

To achieve the foregoing and other objects, and in accordance with the purposes of the present invention, as embodied and broadly described herein, an atmospheric pressure plasma processing reactor comprises a table for holding and moving a wafer to be processed, with at least one electrode being situated in close proximity to the table and defining an entry for introduction of a gas mixture. Wherein, with a radio-frequency voltage connected between the translatable table and the at least one electrode and the gas mixture introduced into the at least one electrode, a plasma is created between the wafer to be processed and the at least one electrode for processing the wafer to be processed as it is moved under the at least one electrode by the table.

In a further aspect of the present invention, and in accordance with its objects and principles, an atmospheric pressure plasma processing reactor comprises at least one wafer processors having grounded electrodes and radio frequency powered electrodes interleaved so that a volume is defined between each of the grounded electrodes and the radio frequency powered electrodes. Wafer transport means transport of the wafers to be processed and placement of each wafer onto one of the electrode pairs (either the grounded electrode or the radio-frequency powered electrode). Gas introduction means introduce a predetermined composition gas mixture into the volume defined between each of the grounded electrodes and the radio frequency powered electrodes. Wherein, with a radio frequency voltage connected between the grounded electrode and the radio frequency powered electrode and the gas mixture in the space between the grounded electrode and the radio frequency electrode, a plasma is created between each electrode pair with the wafer present on one of the selected electrodes in order to achieve photoresist stripping or other means of substrate treatment accomplished by exposure to a chemically-reactive plasma.

In a still further aspect of the present invention, and in accordance with its objects and principles, an atmospheric pressure plasma processing reactor comprises two or more wafer processors, each wafer processor having grounded electrodes and radio frequency powered electrodes interleaved so that a volume is defined between each of the grounded electrodes and the radio frequency powered electrodes. A single enclosure encloses the two or more wafer processors. Wafer transport means transport wafers to be processed from a first wafer processor to a second wafer processor inside the single enclosure and places each wafer onto either the grounded electrodes or the radio frequency powered electrodes. Gas introduction means introduce a predetermined composition gas mixture between each of the grounded electrodes and the radio frequency powered electrodes. Wherein, with a radio frequency voltage connected between the grounded electrode and the radio frequency powered electrode, and with the gas mixture in the volume between the grounded electrode and the radio frequency electrode, a plasma is created between the grounded electrodes and the radio frequency powered electrodes for processing the wafers.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1 is a schematical side view of one embodiment of the present invention showing two processing stations.

FIG. 2 is a schematical side view of another embodiment of the present invention showing two processing stations with slotted electrodes of different aspect ratio (one portion of which has no slots).

FIG. 3 is an end view of an embodiment of the present invention.

FIG. 4 is a top view of an embodiment of the present invention.

FIG. 5 is a graph of PR thickness versus distance for wafer processing between two parallel flat electrodes.

FIG. 6 is a graph of PR thickness versus distance for a variety of slot or groove width under the conditions of the graph in FIG. 5.

FIG. 7 is schematical side view of another embodiment of the present invention showing equally spaced and interleaved ground and radio frequency powered electrodes as well as the gas introduction and heating arrangements.

FIG. 8 is a schematical top view of wafer processing assembly according to the present invention showing two sets of interleaved electrodes of FIG. 4, each being capable of handling a predetermined gas mixture, and a multiple wafer handling spatula.

FIGS. 9A and 9B are illustrations of the top and side views of one embodiment for the wafer handling spatula showing a vacuum chuck for holding the wafers.

### DETAILED DESCRIPTION

The present invention provides plasma processing of substrates and allows substrates to undergo sequential processing by multiple plasma processors using a single enclosure and a robotic stage. The invention can be understood most easily through reference to the drawings.

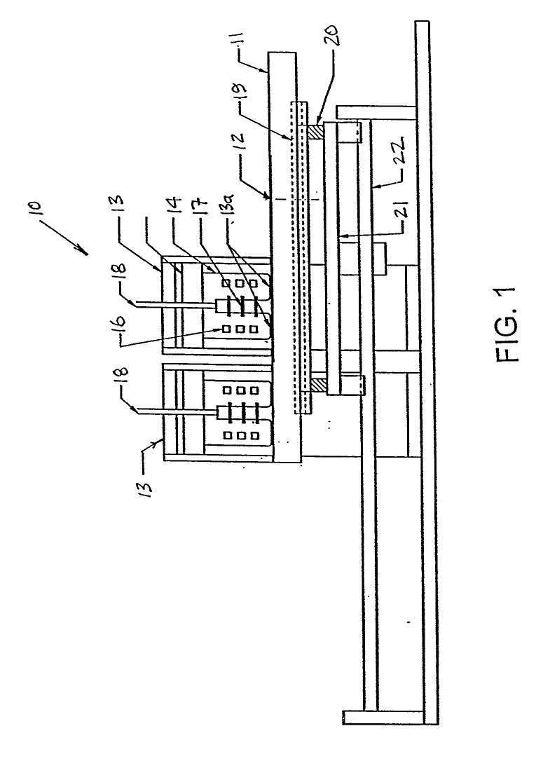

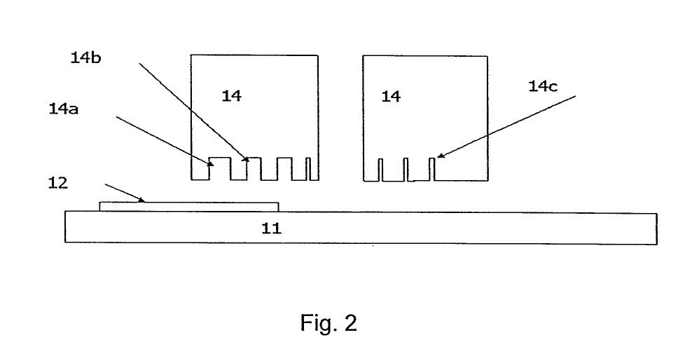

In FIG. 1, a schematical plan view of one embodiment of the invention is shown where plasma processing reactor 10 has wafer table 11 for transporting wafer 12 to be processed by an atmospheric pressure plasma jet. This atmospheric pressure plasma 13a is created in atmospheric pressure plasma jet processors 13, in this figure showing two atmospheric plasma jet processors 13. Atmospheric pressure plasma processors 13, each contain an electrode 14, shown in side-view in FIG. 1. Each electrode 14 has optional temperature control channels 16 and gas baffles 17. An appropriate processing gas is introduced between the two electrodes 14 through gas inlets 18. As shown in FIG. 2 electrodes 14 may have optional grooves, 14a, 14b, 14c, cut into it to provide plasma of sequentially reduced ion density, or “aggressiveness”. The gentlest plasma would be on the portions of electrodes 14, which have no grooves.

With the application of a voltage between either electrode 14 and wafer table 11, and introduction of an appropriate gas through gas inlets 18, a plasma 13a will be created for processing wafer 12 as it is carried through the plasma by wafer table 11. Appropriate temperature control fluids such as air, water or oil, at some desired temperature, are circulated through temperature control channels 16 when necessary to regulate the temperature of electrode 14. In some cases, it also might be desirable to heat the electrodes 14, either resistively, or by passing a heated fluid through the fluid channels 16. In either case, fluid channels 16 are used together with a circulating fluid to control the temperature of gas striking the wafer 12.

Wafer table 11 sits above electric heating rods 19. Heating rods 19 serve to heat wafer 12 to an appropriate temperature for processing when such action is required. Electric heating rods 19 are supported by ceramic insulators 20, which, in turn, rest on slide carriage 21. Slide carriage 21 slides along translating slide rails 22 when slide carriage 21 is moved as described below. In certain embodiments, wafer 12 can remain stationary and electrode 14 can be moved over wafer 12. It only is necessary that relative movement between wafer 12 and electrode 14 be created. It is also possible, and in some cases, desirable, to move processors 13 relative to substrate or wafer 12, while keeping wafer 12 stationary on wafer table 11. One case in which movement of the processor 13 would be preferable is when wafer 12 is large and massive and therefore subject to damage or distortion by its movement or when heavier motors are required to move wafer 12 than to move processors 13. As wafer 12 is moved across electrode 14, it is first subjected to a dense plasma, useful for removal of the hardened photoresist layer, and as wafer 12 continues its movement across electrode 14 it is then subjected to a more gentle plasma, useful for removal of the softer photoresist under the hardened layer. In this way, damage to wafer 12 is avoided once the photoresist layer is fully removed.

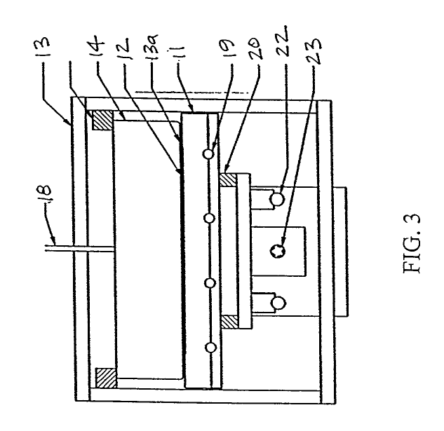

Referring now to FIG. 3, there can be seen an illustration of an end view of this embodiment of the present invention, where many elements are shown that were hidden in FIG. 1. Here, it can be seen that wafer table 11 with wafer is moved under electrode 14 by conventional slide drive screw 23. Slide drive screw 23 can be turned in any convenient manner such as by hand or by a variable-speed motor. Also shown, here in cross section, are electric heating rods 19, which can be controlled by a thermostat (not shown) to regulate the temperature of wafer 12 for a particular processing regimen.

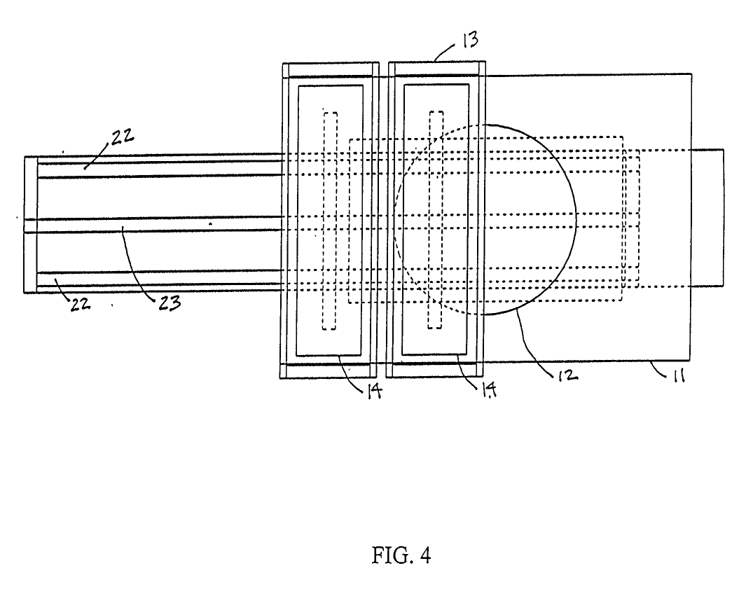

Turning now to FIG. 4, there can be seen a top view of this embodiment of the present invention in which two atmospheric pressure plasma processors are shown. This FIG. 4 shows clearly how wafer table 11 transports wafer 12 under electrodes 14. This transport of wafer table 11 is provided by slide drive screw 23, while sliding along slide rails 22. Also shown are atmospheric pressure plasma jet processors 13, inside which the processing of wafer 12 is accomplished. Variations of this approach are possible. For example, the first processor 13 may operate with a fluorine-containing process gas, whereas the second processor 13 may operate with an oxygen-containing process gas. Alternatively, the first processor may be fitted with grooves of selected dimension, which can be orientated either perpendicularly to the direction of travel, or at some angle ranging from 0 to 90 degrees relative to the direction of movement, whereas the second processor may have no grooves or may have grooves having a different aspect ratio. Or, the first processor may have both grooves and a different process chemistry from the second processor, which may or may not have grooves. Also, instead of moving the wafer in a linear fashion, the wafer may be mounted on a table that might be rotated, thereby moving the wafer and causing it to pass through one or more sections of plasma under electrodes 14.

Although the FIGS. 1-4 illustrate an embodiment of the present invention utilizing two electrodes 14, the invention is not limited to two electrodes 14. Any appropriate number of electrodes 14 could be utilized, from one to many, depending on the processes to be employed for a particular wafer 12. These electrodes 14 could be employed along with subsequent process steps, including wet rinses, all within the traverse of slide carriage 21.

In the present invention, electrode 14 is one electrode and wafer table 11 is the other electrode for connection of the RF energy for creation of a plasma. Either one may be RF-powered, and typically, one is grounded. In most cases, it is convenient to have electrode 14 be rf-powered and wafer table 11 be grounded for safety reasons. The specific frequency of the RF energy and its voltage level are to be determined for the particular process step to be employed for a particular wafer 12.

It is to be understood that in utilizing individual electrodes 14, each electrode 14 can be controlled independently, both with respect to RF energy and process chemistry, while wafer 12 is moved below each electrode 14. A true plasma, including ions and electrons, as well as neutral, chemically-reactive species, exists in the space 13a between electrodes 14 and wafer 12 (FIGS. 1 and 2). The density, or aggressiveness of this chemistry, may be controlled both by the varied application of radio frequency power and by the number, size and shape (or absence of shape thereon) of the grooves.

It is a clear advantage of the present invention that individual electrodes 14 can be powered differently than others, and can employ different process gas mixtures for particular etching situations. For example, one electrode 14 could have a He/CF₄ gas mixture introduced through its gas inlet 18 (FIGS. 1 and 2), while a second electrode 14 could have a He/O₂ gas mixture introduced through its gas inlet 18.

As wafer 12 is moved under each electrode 14, or as processor 13 is moved relative to wafer 12, wafer 12 is processed for two process steps instead of the one step in the conventional reactor. In this embodiment, a third electrode 14 could be used for passivation of wafer 12, with use of a gas mixture of He/H₂ for the plasma.

The oxygen plasma has better selectivity to silicon (i.e., it will preferentially etch the photoresist without etching the silicon under the photoresist, whereas the fluorine-based plasma will etch both). In conventional plasma systems operating in vacuum, this requires two processes chambers (one for the fluorine plasma and one for the oxygen plasma) to avoid cross contamination. This invention improves operation of the ashing process by eliminating the need for separate process chambers.

Also, because this embodiment of the present invention processes a single wafer 12 in each plasma formed between electrode 14 and grounded wafer table 11, it is not subject to the accumulation of particles and etch products, as might occur in a solvent cleaning process, such as wet chemical etching systems. Thus, this embodiment is inherently both dry and clean. Operational savings result because there is no need to dry wafer 12 or to dispose of solvents. In addition, the present invention can perform multiple process steps nearly simultaneously, a feat that is not possible with wet processes, and can do so with lower capital equipment cost and with a considerably smaller footprint, or equipment size.

### EXAMPLE

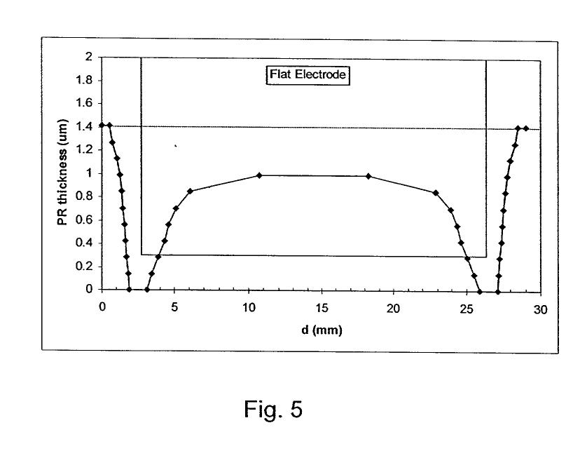

FIG. 5 shows data illustrating the localized observed photoresist film thickness of a 1.4 micron thick photoresist film exposed to a He+O₂ plasma operating at 30 W (6.25 W/cm2) plasma with the wafer at room temperature after 6 minutes of exposure to the plasma. The He flow was 19.5 slpm; and the O₂ flow was 0.13 slpm. The RF frequency was 13.56 MHz. No external heating or cooling was applied to the rf and ground electrodes. Note that the wafer was not moved under the electrode, but was held stationary. Faster etching is observed at the corners of the electrodes, compared to the center of the electrode, as seen by the thicker film remaining at the center after this ashing time. In fact, only 30% of the photoresist is removed at the center of the electrode. This nonuniformity, however, would not be a problem if the wafer is translated across the electrode as described above.

However, if the same electrode is fitted with slots, as shown in FIG. 2, a higher ashing rate is seen over the slots, and a higher average ashing rate is achieved over the entire area of the electrode, relative to the flat electrode, shown in FIG. 1. FIG. 2 shows the localized film thickness for the same conditions as FIG. 1, but using different slots as indicated in FIG. 2. For these tests, the distance between the slots was kept the same: 1.5 mm. The number given in the slots shown in FIG. 2 denote the thickness of the slot. In contrast to FIG. 1, the use of the slotted electrode shown in FIG. 2 resulted in 75% removal of the total photoresist film under the same conditions of flow, radio frequency and power.

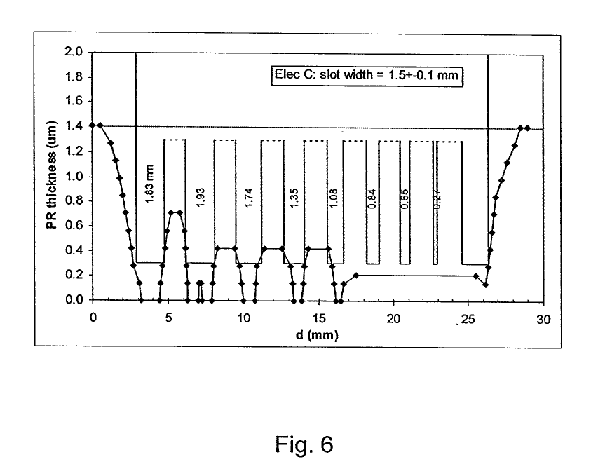

FIG. 6 illustrates the PR Etching pattern for grooved electrodes as illustrated in FIG. 2, and for the same conditions described for FIG. 5. FIG. 6 shows the highest overall rates for photoresist etching are obtained for a pattern of grooves with a separation of 1.5 mm and with a groove thickness between 1 and 2 mm under these process conditions. Better results might be obtained by reducing the separation between the grooves, however this was not tested.

It is believed that the photoresist removal rate enhancement seen in FIG. 6 relative to FIG. 5 results from the formation of a more “aggressive” plasma, having increased ion bombardment rate. Evidence for this was visually seen by the presence of a brighter emission region directly below each of the grooves, indicating a more dense plasma.

For gentle ashing, though, which is desirable near the end of the photoresist removal process (to avoid wafer damage), it would be favorable to expose the wafer to a flat part of the electrode, i.e., a section of the electrode not having grooves or having grooves of much smaller dimensions. In this way, as the wafer is translated across the electrode (which is not done in the testing illustrated in FIG. 5 or 6) the wafer is first exposed to the grooved section of the wafer, having fast etching, and then is exposed to the flat section of the wafer, having slower and more gentle etching.

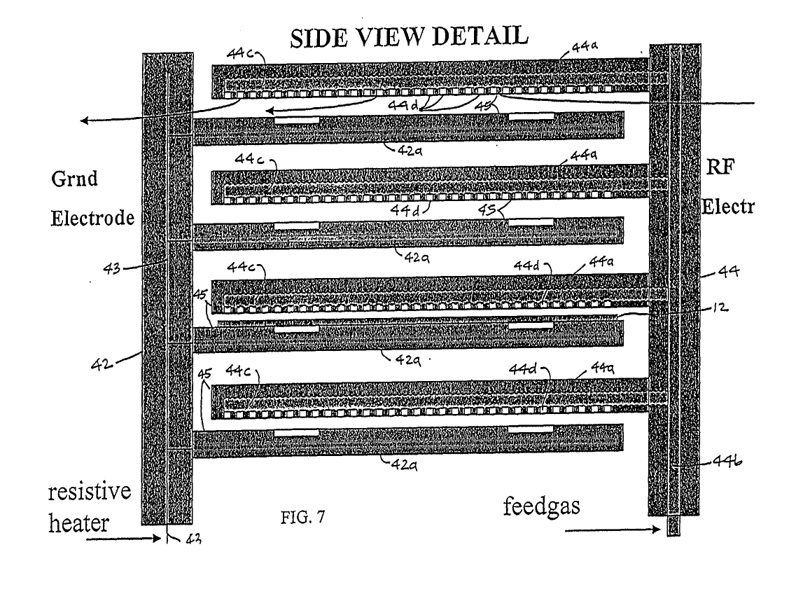

Another embodiment of the present invention is illustrated in a plan view in FIG. 7. In this embodiment, multiple wafers 12 can be processed at the same time. As shown, plasma processor 41 has a ground electrode 42 having projections 42a that project perpendicularly from ground electrode 42. Although four projections 42a are shown in FIG. 4, any number can be used depending on the requirements of a particular application. It is on each of projections 42a that multiple wafers 12 are individually placed for processing. Projections 42a provide a raceway for resistive heater wiring 43 used to heat wafers 12 during processing.

RF electrode 44 similarly has projections 44a that overlie projections 42a with a small volume between to allow for wafers 12 and for the flow of plasma. As in FIG. 2, the RF electrodes 44 in FIG. 7 may have grooves to create a more aggressive plasma and the aspect ratio of the grooves may be varied to provide more or less ion density. The set of projections 42a and projections 44a becomes electrode pair 45. As illustrated, RF electrode 44 defines passage 44b that connects to passages 44c in projections 44a for passage of a feedgas. Projections 44a also define nozzles or openings 44d in projections 44a, also called a showerhead, that allow the applicable feedgas to flow above and around multiple wafers 12. A-“showerhead” consists of a series of small holes in a regular pattern that in practice could be in either one of grounded electrode 42 or RF electrode 44, and is used for uniform distribution of gas into the plasma volume between electrode pair 42a, 44a. The showerhead may be used together with a grooved electrode by placing the holes needed for gas flow, through the grooves. A similar showerhead design may be used in the embodiment shown in FIG. 1, as a replacement for the gas channels denoted by 18 and the gas baffles 17 (FIG. 1).

It is to be noted that although only four sets of interleaved projections 42a and projections 44a are shown in FIG. 7, any number can be used that is appropriate for a specific application. A suggested number of sets for high production is twenty five, which enables this high throughput system to simultaneously process an entire “boat” of wafers at once.

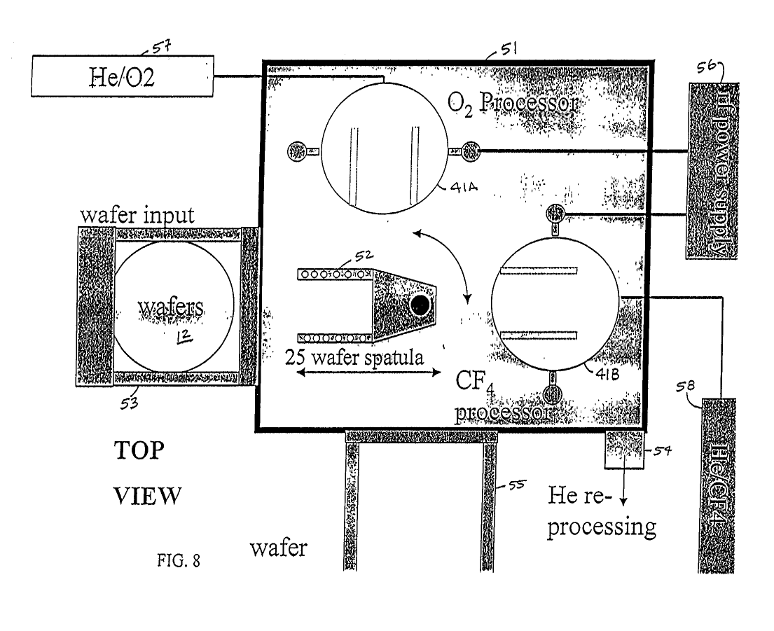

Reference should now be directed to FIG. 8, where a top view of an application of this embodiment of the invention is illustrated schematically. As shown, enclosure 51 encloses two plasma processors 41A and 41B that can be used with the same or different gas mixtures. However, this is for illustration only and any number of plasma processors 41 can be used in enclosure 51, from one up to any desired number to accomplish the desired processing steps. As in the previous embodiment, each processor 41 may have grooves present in each electrode pair 45 in order to control the density, or aggressiveness, of the plasma. Accordingly wafer set 12 may be moved from the first processor 41 having grooves to a second processor 41 either not having grooves or having grooves smaller in size than the first processor in order to obtain a reduction in aggressiveness of the plasma, required as the hardened photoresist skin is removed.

It should be noted that enclosure 51 is a sealed enclosure but not vacuum tight. It is sealed to minimize contamination and to allow for the recovery of helium through He reprocessing or recirculation system 54 and to prevent operator exposure to hazardous process gases.

Wafer spatula 52 picks up wafers 12 from wafer input 53 and moves them to the desired plasma processor 41A and extends onto a corresponding electrode, either one that is projection 42a (FIG. 7) or one that is projection 44a, as the configuration shown in FIG. 7 could be reversed. During processing of wafers 12, each section of wafer spatula 52 is physically and electrically in contact with one of the corresponding projections 42a, 44a by mating with the slots of projections 42a or 44a. When that processing step is completed, wafer spatula 52 retracts from projections 42a or 44a along with wafers 12 and transports the entire set of wafers 12 into the other plasma processor 41b, again with spatula 52 being in electrical and physical contact with the corresponding projection 42a or 44a in processor 41B. After that processing step is completed, wafer spatula 52, still holding wafers 12 retracts and may be moved to yet another processor inside the same chamber (not shown), or may be placed into wafer output 55.

RF power supply 56 is located outside of enclosure 51 and provides RF power to RF electrodes 44 of plasma processors 41. The same RF power supply 56 or different rf power supplies may be used for each of the processors shown in FIG. 8. The frequency of RF power supply 56 can be chosen to be appropriate for the particular feedgases used. As used herein, radio frequency operation means use of an alternating voltage having a frequency that is between 200 KHz and 600 MHz. Generally, a frequency of 13.56 MHz is used for many applications and is the frequency used in the preferred embodiment.

Gas delivery 57 provides the desired gas mixture to one plasma processor 41A and passages 44c (FIG. 7) while gas delivery 58 provides the same or a different gas mixture to the other plasma processor 41B. In one embodiment, gas delivery 57 provides a helium (He) and oxygen (O₂) mixture to one processor and gas delivery 58 provides a helium and carbon tetrafluoride (CF₄) mixture to a second processor. Other halogen-containing feedstocks may also be used, such as NF₃, C₂F₆, Cl₂, CF₃H or SF₆, with much of the same result. CF₄ is the preferred embodiment because it is non-hazardous, inexpensive and readily available. Operation of all of the wafer processors 41 using a high mixture of He (85-99%) is preferred because a stable, non-arcing plasma may be achieved without the need for dielectric covers on either of the projections 42a, 44b, and because substrates of all kinds (semiconductors, dielectrics and metals) may be processed without arcing. Additional processors 41 may be used, each with the same or different gas chemistries. Also, as previously mentioned, the electrode surface may be flat or topographically-shaped, using grooves, in order to obtain a more aggressive plasma.

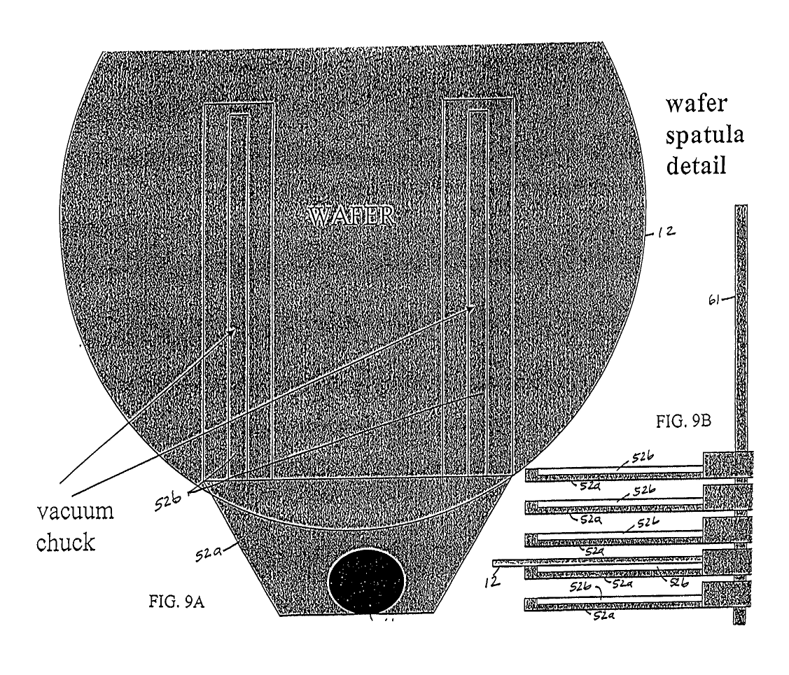

Reference should now be directed to FIGS. 9A and 9B,where top and side views of one wafer holder 52a of wafer spatula 52 are illustrated in schematic form. In FIG. 9A, a top view shows how wafer holder 52a of wafer spatula 52 holds wafers 12 using vacuum chuck 52b and is attached to rotatable shaft 61. Other means may be used of holding wafer 12 to avoid loss or breakage of wafers 12 during transport, including electrostatic chucks, wafer clips or shallow wells, the size of the wafer being machined into the wafer holder 52a.

Turning now to FIG. 9B, there can be seen five wafer holders 52a installed onto rotatable shaft 61, and in one case see how vacuum chuck 52b retains a wafer 12. Actually, any appropriate number of wafer holders 52 can be used for a particular application. However, in normal practice, each section of wafer holder 52a of wafer spatula 52 (in FIG. 8) would hold an individual wafer 12 and there would be more than 5 sections of wafer holders 52a and vacuum chucks 52b comprising multiple wafer spatula 52. The preferred embodiment would have wafer spatula 52 holding 25 wafers 12 at once. Also, note that vacuum chucks are not generally usable in vacuum-based wafer processing unit.

The present invention offers other advantages over the prior art. First, it eliminates the need for any vacuum equipment, simplifying maintenance of the equipment and greatly reducing the cost of the equipment. Second, it etches or cleans wafers or substrates faster because of high reactive species gas density and in-situ exposure to the plasma, so its throughput is greater. Third, it has the ability to run multiple process steps almost simultaneously, even those requiring different process chemistries, resulting in reduced equipment and process complexity. Finally, wafer handling is faster as multiple wafers are moved simultaneously, rather than sequentially, also enhancing wafer throughput.

As previously discussed previously, it was desirable in the use of prior art vacuum-based plasmas, to operate a single process in a single vacuum chamber for each wafer or substrate. This was done because the use of different process chemistries in the same vacuum chamber causes particle contamination to occur, which is a leading cause of defects during wafer processing. As previously mentioned, the use of different process chemistries and the use of a more aggressive plasma, such as a reactive ion etching plasma, was helpful in removing hardened, or carbonized, photoresist. Thus, to use different process chemistries, process conditions, and to avoid contamination problems, requires that multiple vacuum chambers be used. When multiple vacuum chambers are used, it means that the wafer must be moved from one chamber to the next, requiring vacuum hardware, such as gate valves between the chambers, and more complex wafer handling in addition to the associated wafer handling delays and expense of dual chamber operation.

The present invention does not require different vacuum chambers or, for that matter, any vacuum chamber at all. It utilizes a single manipulator to move the wafer through one or more process units, each having the same or different plasma chemistry, and without the associated need for vacuum loadlocks in between. A single process enclosure is used to prevent operator exposure to the process off-gases. However, the effect of multiple vacuum chambers is achieved through the use of multiple independently controlled processors. Use of atmospheric pressure operation, combined with the close proximity of the electrode pairs 14 (FIG. 1), or electrode pairs 45 (FIG. 4) with wafers 12 located inside the small volume of the plasma allows each individual wafer 12 to receive individual exposure to one or more plasma process steps as they progress simultaneously from one processor to another processor, all inside a single enclosure. Because the gas pressure in the plasma region of each electrode pair in processor unit is slightly in excess of atmospheric pressure (to achieve positive gas flow) the likelihood of cross contamination resulting from gas flow in one process unit entering the adjacent electrode pair or from the second processor 41A or 41B, is minimal. Diffusion is slow in this situation, owing to the high-pressure operation of each process unit, so cross contamination problems are avoided.

Applications of the present invention are many and varied. For example, it can be used to etch photoresist, silicon and metal from semiconductor wafers. It can also be used to deposit thin films, including especially large area deposition for thin-film transistor passivation, coatings used for architectural window glass, and deposition of magnetic films or hermetic coatings on magnetic media. Additional applications exist and still others are likely to be discovered through use of the present invention.

Similarly, the present invention provides a means to expose a wafer to sequentially different process conditions, such a highly aggressive plasma (typical of reactive ion etching) to a very gentle plasma (typical of downstream processing) all within the same processor or in adjacent processors, which can treat wafers without the need for moving wafers between separate vacuum chambers.

The foregoing description of the embodiments of the invention has been presented for purposes of illustration and description. It is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. An atmospheric pressure plasma processing reactor comprising:
an electrically conductive table for holding and moving a wafer to be processed along a defined track;
at least one atmospheric pressure plasma processor, said at least one atmospheric pressure plasma processor having an electrically conductive electrode situated in close proximity to said electrically conductive table, and defining an entry for introduction of a gas mixture;
wherein with a radio-frequency voltage connected between said electrically conductive table and said electrically conductive electrode of said least one atmospheric pressure plasma processor and said gas mixture introduced into said at least one atmospheric pressure plasma processor, a plasma is created between said wafer to be processed and said electrically conductive electrode of said at least one atmospheric pressure plasma processor for processing said wafer to be processed during relative movement of the wafer and electrically conductive electrode.

2. The atmospheric pressure plasma etching reactor described in claim 1 further comprising grooves having preselected widths in at least one of said electrically conductive electrodes.

3. The atmospheric pressure plasma etching reactor described in claim 1 wherein said electrically conductive electrodes are flat.

4. The atmospheric pressure plasma etching reactor described in claim 1 further comprising temperature control channels in said least one atmospheric pressure plasma processor.

5. The atmospheric pressure plasma etching reactor described in claim 1 further comprising at least one of the following: baffles, nozzles or a showerhead, for uniformly distributing said gas mixture throughout said least one atmospheric pressure plasma processor.

6. The atmospheric pressure plasma etching reactor described in claim 1 further comprising controllable heating elements in said electrically conductive table.

7. The atmospheric pressure plasma etching reactor described in claim 1 further comprising a motor for moving said at least one electrically conductive electrode.

8. The atmospheric pressure plasma etching reactor as described in claim 1 wherein said least one atmospheric pressure plasma processor consists of one atmospheric pressure plasma processor.

9. The atmospheric pressure plasma etching reactor as described in claim 1 wherein said at least one atmospheric pressure plasma processor comprises two atmospheric pressure plasma processors.

10. The atmospheric pressure plasma etching reactor as described in claim 1, wherein said gas mixture comprises helium and carbon tetrafluoride.

11. The atmospheric pressure plasma etching reactor as described in claim 1, wherein said gas mixture comprises helium and oxygen.

12. The atmospheric pressure plasma etching reactor as described in claim 1, wherein said gas mixture comprises helium and hydrogen.

13. The apparatus as described in claim 1 further comprising at least one of the following: baffles, nozzles or a showerhead, in said radio frequency powered electrode for uniformly distributing said gas mixture throughout said least one atmospheric pressure plasma processor.

14. An atmospheric pressure plasma processing reactor comprising:
at least one wafer processor having grounded electrodes and radio frequency powered electrodes interleaved and defining a pair of electrodes with a volume defined between said electrode pairs;
wafer transport means for transporting wafers to be processed and placing each wafer between and onto ones of said grounded electrode or said radio frequency powered electrode of said pair electrodes;
gas introduction means for introducing a predetermined composition gas mixture between each of said electrode pairs;
wherein, with a radio frequency voltage connected between said electrode pairs and with the gas mixture in said volume between said electrode pairs, a plasma is created between said electrode pairs that is used for stripping or other means of wafer treatment accomplished by exposure to a chemically-reactive plasma.

15. The apparatus as described in claim 14 further comprising an enclosure surrounding said atmospheric pressure plasma processing reactor.

16. The apparatus as described in claim 14, wherein said wafer transport means includes a vacuum chuck for holding said wafers.

17. The apparatus as described in claim 14, wherein said electrodes further comprises grooves having preselected widths in each radio frequency powered electrode.

18. The apparatus as described in claim 14, wherein said radio frequency powered electrodes are flat.

19. The apparatus as described in claim 14, wherein said wafer transport means and said wafers become an electrical and physical part of said electrode pair during processing of said wafers.

20. The apparatus as described in claim 14 wherein said predetermined composition gas mixture is helium and oxygen.

21. The apparatus as described in claim 14 wherein said predetermined composition gas mixture is helium and carbon tetrafluoride.

22. The apparatus as described in claim 14 further comprising controllable heating elements in said electrode pair.

23. The apparatus as described in claim 14 further comprising at least one of the following: baffles, nozzles or a showerhead, in said radio frequency powered electrode for uniformly distributing said gas mixture throughout said least one atmospheric pressure plasma processor.

24. An atmospheric pressure plasma processing reactor comprising:
two or more wafer processors each wafer processor having grounded electrodes and radio frequency powered electrodes interleaved so that a volume is defined between each of said grounded electrodes and said radio frequency powered electrodes;
a single enclosure enclosing said two or more wafer processors;
wafer transport means for transporting wafers to be processed from a first wafer processor to a second wafer processor inside said single enclosure and placing each wafer onto either said grounded electrodes or said radio frequency powered electrodes;
gas introduction means for introducing a predetermined composition gas mixture between each of said grounded electrodes and said radio frequency powered electrodes;
wherein, with a radio frequency voltage connected between said grounded electrode and said radio frequency powered electrode and with the gas mixture in said volume between said grounded electrode and said radio frequency electrode, a plasma is created between said grounded electrodes and said radio frequency powered electrodes for processing said wafers.

25. The apparatus as described in claim 24 wherein said wafer transport means includes a vacuum chuck for holding said wafers.

26. The apparatus as described in claim 24, wherein said wafer transport means and said wafers become an electrical and physical part of said grounded electrodes or said radio frequency electrodes during processing of said wafers.

27. The apparatus as described in claim 24 wherein said predetermined composition gas mixture is helium and oxygen.

28. The apparatus as described in claim 24 wherein said predetermined composition gas mixture is helium and carbon tetrafluoride.

29. The apparatus as described in claim 24 further comprising controllable heating elements in either said grounded electrodes or said radio frequency powered electrodes.

30. The apparatus as described in claim 24 further comprising one of the following: baffles, nozzles or a showerhead, located in said radio frequency powered electrodes or in said grounded electrodes for uniformly distributing said gas mixture throughout said least one atmospheric pressure plasma processor.

31. The apparatus as described in claim 24 further comprising a series of grooves having preselected widths in at least one or more said grounded electrodes or radio frequency electrodes in said wafer processors.

32. The apparatus as described in claim 24 wherein said grounded electrodes and said radio frequency powered electrodes are flat.
